(19) United States
(12) Patent Application Publication
(10) Pub. No.: US 2011/0195202 A1
(43) Pub. Date: Aug. 11, 2011

(54) OXYGEN PUMP PURGE TO PREVENT REACTIVE POWDER EXPLOSION

(75) Inventor: Jonathan C. Dahm, Austin, TX (US)

(73) Assignee: APPLIED MATERIALS, INC., Santa Clara, CA (US)

(21) Appl. No.: 12/704,389

(22) Filed: Feb. 11, 2010

(51) Int. Cl. C23C 16/44; C23C 16/00

(52) U.S. Cl. 427/569; 118/723 R

(57) ABSTRACT

A method of managing particles and material accumulation in exhaust components used in deposition systems is provided. More specifically, embodiments of the present invention relate to methods of preventing build-up of explosive material in vacuum forelines of deposition systems. In one embodiment, a short purge of oxygen-containing gas may be introduced into the foreline during or in between cycles of deposition of a layer on the substrate in order to oxidize at least a portion of combustible processing by-products in the foreline. In one embodiment, at least a portion of the processing by-products and oxygen-containing gas react to form silicon dioxide (SiO₂).

### BACKGROUND OF THE INVENTION

1. Field of the Invention

Embodiments of the present invention generally relate to methods of managing particles and material accumulation in exhaust components used in deposition systems. More specifically, embodiments of the present invention relate to methods of preventing build-up of explosive material in vacuum forelines of chemical vapor deposition systems.

2. Description of the Related Art

Some silicon deposition processes can generate highly reactive silicon powder. In particular, the deposition of microcrystalline silicon, such as in solar applications, tends to form chunks of silicon which then fall down the vacuum exhaust line of the deposition chamber, commonly called the foreline. If many deposition cycles are run in a process chamber using silane or other similar compounds, powder or particles are deposited in the vacuum forelines between the chamber and the vacuum pumps. After many deposition cycles, a significant amount of surface area of highly reactive and/or un-oxidized material can be found in this deposited material found coating the foreline pipes. If the dust or particulate is subsequently exposed to air, such as during maintenance, there can be a violent reaction and even an explosion.

Several methods have been used to prevent a build-up of or help dispose of explosive silicon powder in the vacuum forelines of chemical vapor deposition (CVD) systems. For example, one solution has been to clean the foreline with NF₃, fluorine, or other gases with an etching property. This solution has been implemented in amorphous silicon deposition processes with some success. However, microcrystalline silicon deposition processes generate more powder than can be effectively etched away in a cleaning step. Another drawback to cleaning the foreline with an etchant is that it is difficult to determine how far down the foreline the silicon is etched. Furthermore, the lines may get hot from the etching process, leading to a potentially explosive situation if unreacted powder remains in the foreline. Another solution which has been proposed includes collecting the dust and mixing it with trifluourotri-chloro-ethane liquid to render a slurry that is then distilled. This solution, however, may not comport with environmental regulations. Yet another solution has been to connect a catch pot at the bottom of the vacuum foreline just upstream of the vacuum pump to collect the reactive powder. However, after many deposition cycles, the catch pot gets full and needs to be emptied out. Emptying out the catch pot is a dangerous procedure because the powder collected is very fine and highly reactive. Moreover, each time the catch pot needs to be emptied leads to process down time.

Therefore, there is a need for a method of safely and effectively handling or disposing of highly reactive silicon dust which forms inside vacuum exhaust forelines.

### SUMMARY OF THE INVENTION

The present invention generally relates to methods of managing particles and material accumulation in exhaust components used in deposition systems. More specifically, embodiments of the present invention relate to methods of preventing build-up of explosive material in vacuum forelines of chemical vapor deposition systems.

In one embodiment, a method of processing a substrate in a deposition chamber is provided, comprising depositing a layer on the substrate, wherein combustible processing by-products are produced in a foreline of the deposition chamber during the depositing step, and flowing oxygen-containing gas into the foreline to oxidize at least a portion of the combustible processing by-products in the foreline.

In another embodiment, a system for processing a substrate is provided. The system comprises a deposition chamber for depositing a layer, a foreline that couples a vacuum pump to the deposition chamber, and a valve to control flow between the deposition chamber and the foreline. The system also includes an oxygen-containing gas supply system, comprising at least one oxygen-containing gas source, an inlet line that connects the at least one oxygen-containing gas source to the foreline, and at least one valve connected to the inlet line to control the flow of an oxygen-containing gas from the oxygen-containing gas source into the foreline, wherein the oxygen-containing gas is adapted to react with processing by-products in the foreline. The system further comprises a catch pot that is adapted to retain at least a portion of the reacted processing by-products.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram representing one embodiment of the present invention;

FIG. 2 is a schematic cross-sectional view of a plasma enhanced chemical vapor deposition (PECVD) chamber and one embodiment of an oxygen pump purge system as described herein; and

FIG. 3 is a top schematic view of one embodiment of a process system having a plurality of chambers and one embodiment of an oxygen pump purge system as described herein for each chamber.

### DETAILED DESCRIPTION

Embodiments described herein provide a method for cleaning exhaust components found in a vacuum deposition system, such as vacuum forelines in chemical vapor deposition systems. More specifically, embodiments of the present invention relate to methods of preventing build-up of explosive material in vacuum forelines of chemical vapor deposition systems. In one embodiment, a short purge of oxygen-containing gas is introduced into the vacuum exhaust foreline during and/or between each deposition cycle in order to react with one or more processing by-products, such as a small amount of residual silicon material that is formed in each deposition cycle, and convert it to unreactive silicon dioxide (SiO₂).

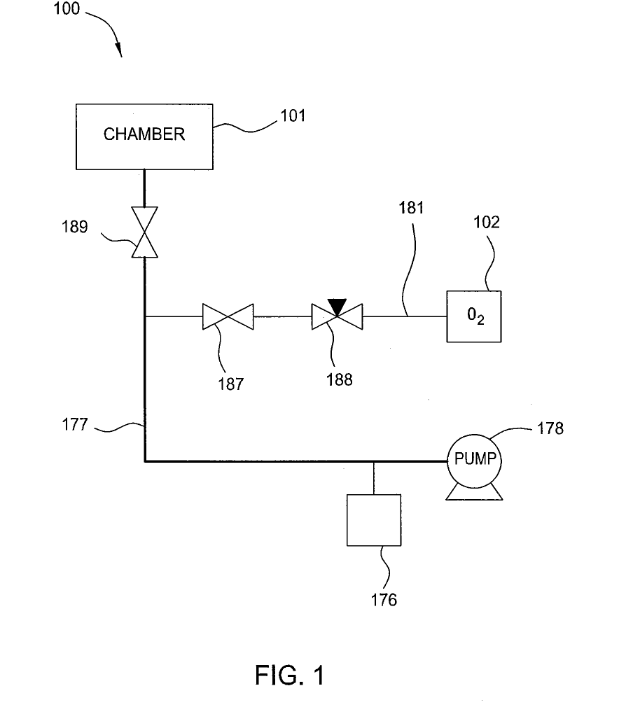

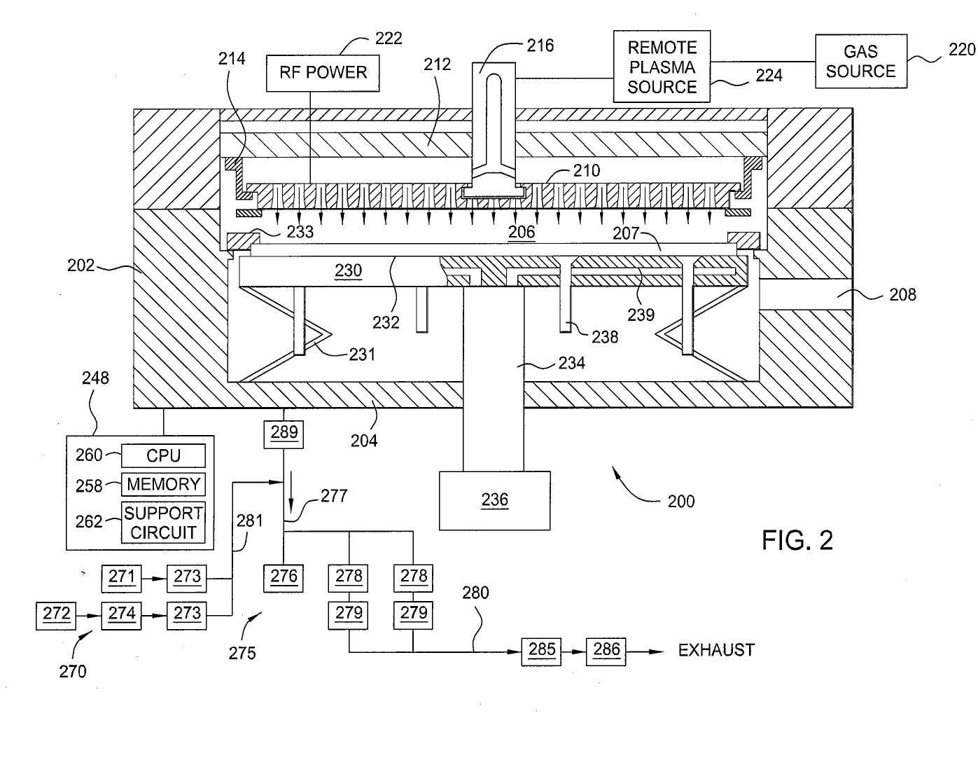

In one embodiment, as illustrated in the simplified process flow diagram of FIG. 1, the conversion of the one or more processing by-products, such as unreacted silicon to silicon dioxide (SiO₂) can be done by connecting an oxygen supply inlet line 181 to a vacuum foreline 177 which is connected to a process chamber 101 (e.g., chamber 200 in FIG. 2). In general, the one or more processing by-products may include gas molecules, partially reacted precursor materials, un-reacted vapor phase compounds, partially reacted particulate material (e.g., silicon-containing powder) and/or other reaction by-products. The oxygen supply inlet line 181 may be connected at one end to the vacuum foreline 177 and at the other end to an oxygen-containing source 102, which may be adapted to deliver pure oxygen (O₂) gas, ozone (O₃) or compressed dry air. Inlet line 181 and vacuum foreline 177 may join at a location on foreline 177 upstream of a vacuum pump 178 and a catch pot 176. The pressure differential at vacuum pump 178 may be fairly high, as the pressure in foreline 177 may be around 1 to 10 Torr. In an alternative embodiment, the oxygen gas can be ionized or oxygen radicals can be formed by use of a remote RF plasma source, so as to enhance the efficiency of the reaction of the reactive materials (e.g., silicon particles, silane) in foreline 177 and the oxygen-containing gas. The oxygen-containing source 102 may supply the oxygen-containing gas at a pressure of about 1 to 3 bar gauge.

A chamber foreline valve 189 may be placed at a section of the foreline just downstream of where foreline 177 connects to the process chamber and upstream of where foreline 177 and inlet line 181 meet. The chamber foreline valve 189 is able to control the amount of fluid communication between the chamber 101 and the foreline 177, and prevent any oxygen or other materials from entering and contaminating the chamber 101 from the foreline 177. A valve 187, such as a pneumatic valve, on the inlet line 181 may be used to start and stop the flow of oxygen to the foreline 177. A control valve 188, such as a needle valve, can be used to control the flow of oxygen in the oxygen supply inlet line 181. The pressure of the oxygen entering foreline 177 should be high enough so that the oxygen has an opportunity to react with the silicon residue, but not too high so as to overwhelm vacuum pump 178. Control valve 188 can be placed upstream or downstream of valve 187. In one embodiment, a mass flow controller can be used instead of a needle valve for control valve 188. The valve 187 could be controlled to turn on the oxygen flow for a brief period of time after each deposition cycle.

During an oxygen purge cycle, the chamber foreline valve 189 is generally closed to prevent reaction or contamination within the chamber. Once chamber foreline valve 189 is closed, a vacuum will remain in the portion of the foreline downstream of chamber foreline valve 189 and any gas present in the foreline will evenly distribute throughout the volume available in the foreline so that no gas and particle mixing schemes are required. In one embodiment, the oxygen purge process will react with the residual silicon material in foreline 177 that is formed during each deposition cycle performed in the chamber and convert it to unreactive silicon dioxide (SiO₂).

In this manner, instead of filling catch pot 176 with reactive silicon residue, running an oxygen purge cycle between deposition cycles (or during the deposition process, depending on the embodiment) will fill the catch pot with unreactive silicon dioxide. Disposing of the silicon dioxide is much safer than having to dispose of reactive material accumulated in the catch pot and risk a potentially dangerous situation. Furthermore, running the oxygen purge cycle in between deposition cycles will result in a safer, smaller, more controllable reaction than if the entire contents of a full catch pot were to react to the exposure to air, because the amount of highly reactive silicon residue can build up. It should be noted that in other embodiments, the oxygen purge cycle may also be run during a deposition cycle, while the chamber is in operation, to react with particles formed during the deposition cycle. In such embodiments, a negative pressure should be maintained in the foreline downstream of the oxygen supply inlet so that the flow of oxygen-containing gas does not enter and contaminate the chamber. The flow of oxygen-containing gas should not be so high as to overwhelm the vacuum pump downstream.

FIG. 2 is a schematic cross-sectional view of a plasma enhanced chemical vapor deposition (PECVD) chamber 200 that can be used with one embodiment of an oxygen pump purge system as described herein. One suitable PECVD chamber is available from Applied Materials, Inc., located in Santa Clara, Calif. It is contemplated that other deposition chambers, including those from other manufacturers, may be utilized to practice the present invention.

The chamber 200 generally includes walls 202, a bottom 204, a showerhead 210, and substrate support 230 which define a processing volume 206. The process volume may be accessed through a valve 208 such that the substrate may be transferred in and out of the chamber 200. The substrate support 230 includes a substrate receiving surface 232 for supporting a substrate 207 and stem 234 coupled to a lift system 236 to raise and lower the substrate support 230. A shadow ring 233 may be optionally placed over the periphery of the substrate 207. Lift pins 238 are moveably disposed through the substrate support 230 to move a substrate to and from the substrate receiving surface 232. The substrate support 230 may also include heating and/or cooling elements 239 to maintain the substrate support 230 at a desired temperature. The substrate support 230 may also include grounding straps 231 to provide RF grounding at the periphery of the substrate support 230.

The showerhead 210 is coupled to a backing plate 212 at its periphery by a suspension 214. The showerhead 210 may also be coupled to the backing plate 212 by one or more center supports 216 to help prevent sag and/or control the straightness/curvature of the showerhead 210. A gas source 220 is coupled to the backing plate 212 to provide gas through the backing plate 212 and through the showerhead 210 to the substrate receiving surface 232. An RF power source 222 is coupled to the backing plate 212 and/or to the showerhead 210 to provide a RF power to the showerhead 210 so that an electric field is created between the showerhead 210 and the substrate support 230 so that a plasma may be generated from the gases between the showerhead 210 and the substrate support 230. Various RF frequencies may be used, such as a frequency between about 0.3 MHz and about 200 MHz. In one embodiment the RF power source is provided at a frequency of 13.56 MHz.

A remote plasma source 224, such as an inductively coupled remote plasma source, may also be coupled between the gas source 220 and the backing plate 212. Between processing substrates, a cleaning gas may be provided to the remote plasma source 224 so that a remote plasma is generated and provided to clean chamber components. The cleaning gas may be further excited by the RF power source 222 provided to the showerhead. Suitable cleaning gases include but are not limited to NF₃, F₂, and SF₆.

A controller 248 may be coupled to the processing chamber 200. The controller 248 includes a central processing unit (CPU) 260, a memory 258, and support circuits 262. The controller 248 is utilized to control the process sequence, regulating the gas flows from the gas source 220 into the chamber 200 and controlling power supply from the RF power source 222 and the remote plasma source 224. The CPU 260 may be of any form of a general purpose computer processor that can be used in an industrial setting. The software routines can be stored in the memory 258, such as random access memory, read only memory, floppy or hard disk drive, or other form of digital storage. The support circuits 262 are conventionally coupled to the CPU 260 and may comprise cache, clock circuits, input/output subsystems, power supplies, and the like. The software routines, when executed by the CPU 260, transform the CPU into a specific purpose computer (controller) 248 that controls the processing chamber 200 such that the processes, such as described above, are performed in accordance with the present invention. The software routines may also be stored and/or executed by a second controller (not shown) that is located remotely from the processing chamber 200.

FIG. 2 generally illustrates a more detailed embodiment of the oxygen purge system. A system of vacuum pumps is coupled to the chamber 200 to control the processing volume 206 at a desired pressure. This vacuum pump system may include a gas supply system 270 and an exhaust system 275. The gas supply system 270 supplies oxygen-containing gas to react with silicon residue in foreline 277 leading from chamber 200 to an exhaust system, such as a scrubber or other similar device. Gas supply system 270 may include one or more gas sources, such as the two shown at 271 and 272. These gas sources may supply an oxygen-containing gas such as pure oxygen, compressed dry air, or ozone. One or more of the gas sources may be connected to a remote plasma source (RPS) 274 located downstream of the gas source 272 which may ionize the gas or form gas radicals. As shown in FIG. 2, the oxygen-containing gas will enter foreline 277 through inlet line 281. Each line coming from the gas sources 271, 272 may also include a valve 273 to control the flow of oxygen-containing gas in inlet line 281. It should be noted that although FIG. 2 shows only one inlet line 281, there may be multiple inlet lines feeding oxygen-containing gas into foreline 277. For example, there may be a separate inlet line connecting each gas source to the foreline 277. In one embodiment, one of the gas sources 271 or 272 may be adapted to deliver a carrier gas, such as nitrogen or argon, to control the pressure in the foreline 277 at a desired time during processing.

As described with reference to FIG. 1, a chamber foreline valve 289, such as a pneumatic valve, may be located downstream of chamber 200 and upstream of where inlet line 281 and foreline 277 join so that when the valve is shut, there is no fluidic communication between the chamber 200 and the section of foreline 277 downstream of the chamber foreline valve 289. Chamber foreline valve 289 keeps oxygen and any other materials in the foreline 277 from contaminating the chamber 200. The volume in the section of foreline 277 downstream of chamber foreline valve 289 will be under vacuum conditions, so that any gases in that section will distribute and fill up the volume available, so that no mixing is required, but is certainly an option.

Any solid particulates in foreline 277 may be deposited in catch pot 276, which may be placed at the bottom of foreline 277 just upstream of the vacuum pumps. Assuming the oxygen introduced by gas supply system 270 reacts with the silicon residue inside foreline 277, the material which accumulates in catch pot 276 will consist mainly of silicon dioxide (SiO₂). Any gases in foreline 277 will then flow towards one or more vacuum pumps. The vacuum pumps may be in a stacked pump configuration, as shown in FIG. 2. For example, one or more roots blowers 278 may each be placed in line with one or more mechanical pumps 279. Exhaust line 280 may carry exhaust from mechanical pumps 279 to a collection vessel 285. As with the gas supply lines, instead of all lines from mechanical pumps 279 joining to form a single exhaust line 280 that is connected to the collection vessel 285, there may be a separate line from each mechanical pump 279 to the collection vessel 285. The vapor phase exhaust can then be diverted from the collection vessel 285 into abatement unit 286 to minimize or eliminate, such as by making inert, any residual by-products that may be hazardous air pollutants before they can be exhausted to the atmosphere.

One example of a deposition process that can be used to form a silicon-containing layer on a substrate, such as a p-type microcrystalline silicon layer, may comprise delivering a gas mixture of hydrogen gas to silane (SiH₄) gas in a ratio of about 200:1 or greater to the processing region disposed over the substrate. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. The flow rates in the present disclosure are expressed as sccm per interior chamber volume. The interior chamber volume is defined as the volume of the interior of the chamber which a gas can occupy. An RF power between about 50 milliwatts/cm² and about 700 milliwatts/cm² may be provided to the showerhead 210. The RF powers in the present disclosure are expressed as Watts supplied to an electrode per substrate surface area. The pressure in the processing volume 206 of the chamber may be maintained between about 1 Torr and about 100 Torr, preferably at about 12 Torr. The pressure in the processing volume 206 is generally controlled by the delivery of the process gases (e.g., silane, hydrogen) from a process gas source, such as gas source 220, and the exhaust of the processing by-products to the vacuum pumps connected to the foreline 277 and exhaust system 275. The deposition rate of the p-type microcrystalline silicon contact layer may be about 10 Å/min or more. The p-type microcrystalline silicon contact layer has a crystalline fraction between about 20 percent and about 80 percent, preferably between 50 percent and about 70 percent. Other examples of other silicon deposition processes performed in a deposition chamber that may be used in conjunction with one or more of the embodiments described herein are disclosed in the commonly assigned U.S. Pat. No. 7,582,515, which is herein incorporated by reference in its entirety.

The substrate processing methods described herein may be especially useful for depositing layers on large area substrates used to form solar cells, such as substrates measuring 2.2 meters by 2.6 meters. The substrate processing methods may be useful for thin film solar processes and batch crystalline silicon processes.

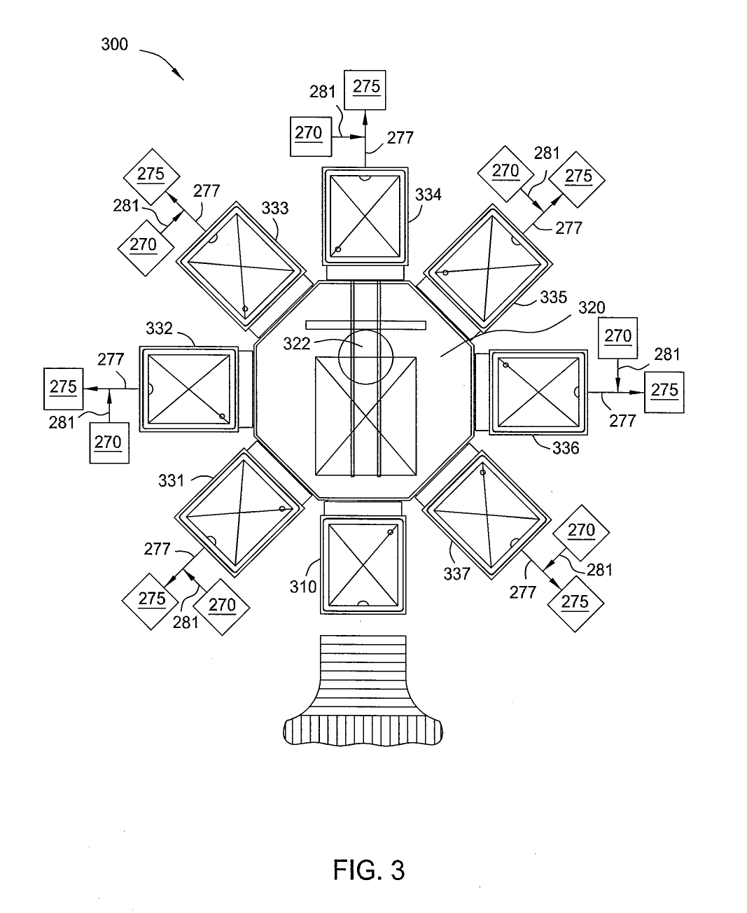

FIG. 3 is a top schematic view of one embodiment of a process system 300 having a plurality of process chambers 331-337, such as PECVD chamber 200 of FIG. 2 or other suitable chambers, such as PVD chambers, CVD chambers, evaporation coating, or other deposition chambers capable of depositing films for solar cells. The process system 300 includes a transfer chamber 320 coupled to a load lock chamber 310 and the process chambers 331-337. The load lock chamber 310 allows substrates to be transferred between the ambient environment outside the process system 300 and vacuum environment within the transfer chamber 320 and process chambers 331-337. The load lock chamber 310 includes one or more evacuatable regions holding one or more substrates. The evacuatable regions are pumped down during input of substrates into the system 300 and are vented during output of the substrates from the system 300. The transfer chamber 320 has at least one vacuum robot 322 disposed therein that is adapted to transfer substrates between the load lock chamber 310 and the process chambers 331-337. While seven process chambers are shown in FIG. 3; this configuration is not intended to be limiting as to the scope of the invention, since the system may have any suitable number of process chambers.

FIG. 3 also shows, for each process chamber 331-337, a gas supply system 270 having inlet line 281 leading to foreline 277 and an exhaust system 275, as described with respect to FIG. 2 above. While FIG. 3 shows an embodiment having a separate gas supply system and exhaust system for each process chamber, other configurations wherein two or more process chambers share a gas supply system and/or exhaust system are envisioned.

Thus, a method of preventing build-up of explosive material in vacuum forelines of chemical vapor deposition systems is provided. By introducing purges of oxygen-containing gas into the vacuum foreline in between or during deposition cycles, explosive silicon particulates can interact and react with the supplied oxygen to form unreactive silicon dioxide, which can accumulate in a catch pot. Between-cycle oxygen purges avoids reacting large quantities of explosive silicon particulates, which can react too quickly and generate too much heat, while minimizing the possibility of contaminating the upstream process chamber. This method also avoids accumulation of highly reactive and highly explosive particulates in catch pots which then need to be carefully disposed of.

While the foregoing is directed to embodiments of the present invention, other and further embodiments of the invention may be devised without departing from the basic scope thereof, and the scope thereof is determined by the claims that follow.

1. A method of processing a substrate in a deposition chamber, comprising:
depositing a layer on the substrate, wherein combustible processing by-products are produced in a foreline of the deposition chamber during the depositing step; and
flowing oxygen-containing gas into the foreline to oxidize at least a portion of the combustible processing by-products in the foreline.

2. The method of claim 1, further comprising shutting gas flow between the deposition chamber and the foreline prior to flowing the oxygen-containing gas into the foreline.

3. The method of claim 1, further comprising catching product of reaction of the combustible processing by-products and oxygen-containing gas in a catch pot connected to the foreline upstream from a vacuum pump.

4. The method of claim 1, wherein the combustible processing by-products comprise silicon-containing particles.

5. The method of claim 4, wherein at least a portion of the processing by-products and oxygen-containing gas react to form silicon dioxide.

6. The method of claim 4, wherein the oxygen-containing gas flows in between layer deposition cycles.

7. The method of claim 4, wherein the oxygen-containing gas flows during the deposition of the layer.

8. A system for processing a substrate, comprising:
a deposition chamber for depositing a layer;
a foreline that couples a vacuum pump to the deposition chamber;
a valve to control flow between the deposition chamber and the foreline;
an oxygen-containing gas supply system, comprising:
at least one oxygen-containing gas source,
an inlet line that connects the at least one oxygen-containing gas source to the foreline, and
at least one valve connected to the inlet line to control the flow of an oxygen-containing gas from the at least one oxygen-containing gas source into the foreline, wherein the oxygen-containing gas is adapted to react with processing by-products in the foreline; and
a catch pot that is adapted to retain at least a portion of the reacted processing by-products.

9. The system of claim 8, further comprising an abatement unit downstream of the vacuum pump.

10. The system of claim 8, further comprising a collection vessel downstream of the vacuum pump.
